(19) United States
(12) Patent Application Publication
(10) Pub. No.: US 2012/0152335 A1
(43) Pub. Date: Jun. 21, 2012

(54) FULL-SPECTRUM ABSORPTION SOLAR CELL

(76) Inventors: Hui-Ying SHIU, Hsinchu (TW); Tri-Rung Yew, Hsinchu (TW)

(21) Appl. No.: 12/973,101

(22) Filed: Dec. 20, 2010

(51) Int. Cl. H01L 31/0256

(52) U.S. Cl. 136/252

(57) ABSTRACT

A full-spectrum absorption solar cell adopts cobalt-doped tin dioxide as an N-type material. Thereby, a solar cell of the present invention can be fabricated by a spray method in a hot pressing fabrication process. The present invention does not need to fabricate a solar cell in a vacuum or furnace system and thus can solve the high cost problem of the conventional technology. The N-type cobalt-doped layer can absorb full spectrum of sunlight. The N-type cobalt-doped layer can be used to fabricate a solar cell with a low-temperature fabrication process. Thus, the present invention does not need to adopt a high-temperature resistant substrate (such as silicon chip or glass) used in the conventional high-temperature fabrication process but can adopt a substrate made of plastic. And, the conversion efficiency of the invention can achieve 1.2%, it is a significant improvement over the oxide-based nanostructures heterojunction solar cells in the world.

### FIELD OF THE INVENTION

The present invention relates to a solar cell, particularly to a full-spectrum absorption solar cell.

### BACKGROUND OF THE INVENTION

Various alternative energies have been developed to solve the problem of petroleum exhaustion. Among them, solar energy attracts the most attention because it has features of inexhaustibility and non-pollution. In a solar cell, a depletion region is formed between a P-type semiconductor material and an N-type semiconductor material to absorb solar energy and converts the solar energy into electric energy. The combinations of different materials and fabrication environments result in different photoelectric efficiency.

For instance, Jingbiao Cui and Ursula J. Gibson disclosed “A Simple Two-Step Electrodeposition of Cu₂O/ZnO Nanopillar Solar Cells” in the Journal of Physical Chemistry C, 2010, 114, p6804-6412, wherein a cuprous oxide film is used as the P-type semiconductor material, and a zinc oxide film is used as the N-type semiconductor material. The conventional solar cell is fabricated in a furnace process condition and has an open-circuit voltage of 0.595 volts, a short-circuit current of 6.78 mA/cm², a fill factor (FF) of 50% and power conversion efficiency (PCE) of 2.01%. However, the cost and energy loss of the furnace process are much higher, thus is increased the fabrication cost.

Moreover, Mittiga, et al. proposed “Heterojunction Solar Cell with 2% Efficiency Based on a Cu₂O Substrate” in Applied Physics Letters 88, 163502. Similarly to the abovementioned technology, the prior art also uses a cuprous oxide (Cu₂O) film as the P-type semiconductor material and zinc oxide nano-pillar as the N-type semiconductor material. The N-type semiconductor material is fabricated by using an electrodeposition process. The solar cell fabricated thereby has an open-circuit voltage of 0.29 volts, a short-circuit current of 8.2 mA/cm², a fill factor of 36% and power conversion efficiency of 0.88%. The solar cell fabricated by using an electrodeposition process has a lower fabrication cost. However, it has poor photoelectric conversion efficiency. Therefore, many researchers in the field are devoted to develop solar cells with lower fabrication cost and higher photoelectric conversion efficiency.

Sunlight is not a single-wavelength ray but has a spectrum ranging from infrared ray to ultraviolet ray. A common solar cell can only absorb a part of the sunlight spectrum, such that other sunlight spectrum is wasted. Among the existing solar cells, only the multilayer structure can absorb full spectrum of sunlight. However, the multilayer solar cell has a complicated and expensive fabrication process. Besides, the multilayer solar cell is made of rare-earth elements or non-environmentally friendly materials. The cost of rare-earth elements impacts mass production of the solar cells. The non-environmentally friendly materials are referred to toxic or pollutant materials, which confront with the environmental protection consciousness existing in the modern society.

### SUMMARY OF THE INVENTION

The primary objective of the present invention is to solve the problem that the conventional solar cell is fabricated at a higher cost.

Another objective of the present invention is to solve the problem that the conventional full-spectrum absorption solar cell is made of multilayer materials and has a complicated fabrication process.

To achieve the abovementioned objectives, the present invention proposes a full-spectrum absorption solar cell, which comprises a substrate, a first electrode layer on the substrate, a P-type semiconductor layer, an N-type cobalt-doped layer, and a second electrode layer. The P-type semiconductor layer is arranged at one side of the first electrode layer far from the substrate and connected with the first electrode layer. The N-type cobalt-doped layer is arranged at one side of the P-type semiconductor layer far from the first electrode layer and connected with the P-type semiconductor layer. The N-type cobalt-doped layer is made of a cobalt-doped tin dioxide (Sn_{1-X}CO_{X}O₂) and connected with the P-type semiconductor layer to form a depletion layer at the junction thereof. The depletion layer absorbs light and generates electron-hole pairs. The second electrode layer is arranged at one side of the N-type cobalt-doped layer far from the first electrode layer and connected with the N-type cobalt-doped layer. Via optical characteristic analysis of oxide, it is known that the absorption spectrum of the cobalt-doped tin dioxide ranges from 700 nm to 1400 nm. The P-type semiconductor layer is made of cuprous oxide (Cu₂O) having an absorption spectrum ranging from 300 nm to 800 nm. The cobalt-doped tin dioxide can successfully absorb full spectrum of the sunlight, and cuprous oxide (Cu₂O) improves the absorption of shorter spectrum. The P-type semiconductor layer may be made of copper oxide (CuO) or cobalt oxide (CO₃O₄) or the like.

The present invention is characterized in adopting cobalt-doped tin dioxide as the N-type semiconductor material. Cobalt-doped tin dioxide can be used to fabricate a solar cell with a spray method in a hot pressing technique. Thereby, the present invention is exempted from the high cost resulting from fabricating a solar cell in the vacuum system or a furnace. Further, the N-type cobalt-doped layer provides full-spectrum absorption capability for a solar cell, and the combination of the N-type cobalt-doped layer and the P-type cuprous oxide (Cu₂O) semiconductor layer improves the wide absorption spectrum of sunlight. Furthermore, the N-type cobalt-doped layer can be used to fabricate a solar cell in a low-temperature fabrication process. Therefore, the substrate of the solar cell can be made of a plastic material in the present invention. Thus, the present invention is exempted from the problem that the conventional high-temperature fabrication process has to adopt a high-temperature resistant substrate such as glass or silicon chip to fabricate a solar cell. The most important of all, the conversion efficiency of the invention can achieve 1.2%, it is a significant improvement over the oxide-based nanostructures heterojunction solar cells in the world.

### BRIEF DESCRIPTION OF THE DRAWINGS

FIG. 1 is a diagram schematically showing the fabrication process of a full-spectrum absorption solar cell according to one embodiment of the present invention;

FIG. 2 is a diagram schematically showing the voltage-current relationship of a full-spectrum absorption solar cell according to one embodiment of the present invention; and

FIG. 3 is a diagram schematically showing the absorption spectrum of a full-spectrum absorption solar cell according to one embodiment of the present invention.

### DETAILED DESCRIPTION OF THE PREFERRED EMBODIMENTS

The technical contents of the present invention are described in detail in cooperation with the drawings below.

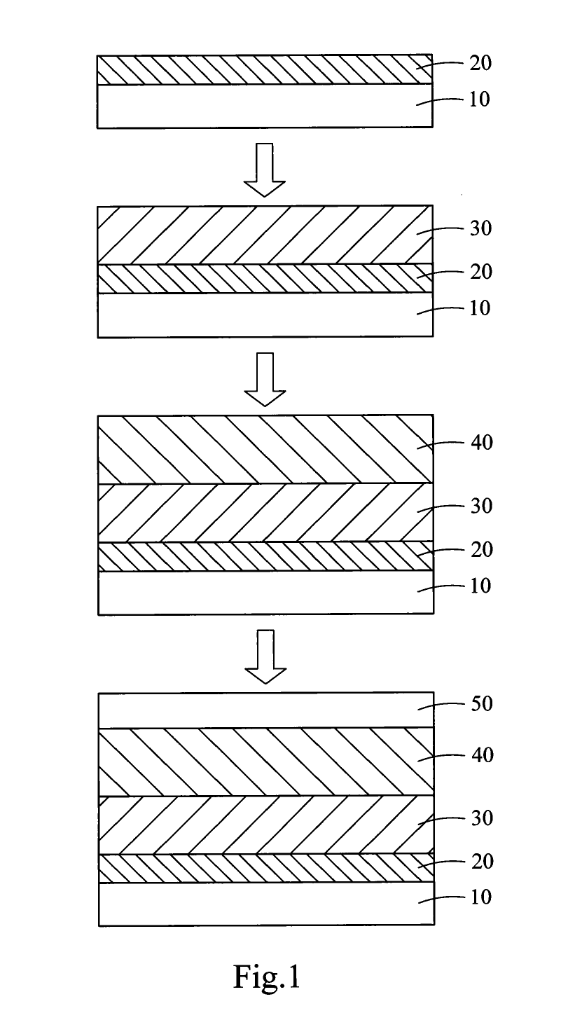

Refer to FIG. 1 a diagram schematically showing the fabrication process of a full-spectrum absorption solar cell according to one embodiment of the present invention. The full-spectrum absorption solar cell of the present invention comprises a substrate 10, a first electrode layer 20 formed on the substrate 10, a P-type semiconductor layer 30, an N-type cobalt-doped layer 40, and a second electrode layer 50. The substrate 10 is made of a material selected from a group consisting of silicon chip, glass or plastic. In this embodiment, the first electrode layer 20 is made of a material selected from a group consisting of platinum, titanium and a combination thereof. The first electrode layer 20 has the metal opaque characteristic and reflects incident light. The P-type semiconductor layer 30 is arranged at one side of the first electrode layer 20 far from the substrate 10 and connected with the first electrode layer 20. The N-type cobalt-doped layer 40 is arranged at one side of the P-type semiconductor layer 30 far from the first electrode layer 20 and connected with the P-type semiconductor layer 30. The N-type cobalt-doped layer 40 is made of cobalt-doped tin dioxide (Sn_{1-X}CO_{X}O₂) and connected with the P-type semiconductor layer 30 to form a depletion layer at the junction thereof. The depletion layer absorbs light and generates electron-hole pairs. The second electrode layer 50 is arranged at one side of the N-type cobalt-doped layer 40 far from the first electrode layer 20 and connected with the N-type cobalt-doped layer 40. In this embodiment, the second electrode layer 50 is a transparent electrode made of a material selected from a group consisting of AZO (Aluminum-doped Zinc Oxide) and ITO (Indium Tin Oxide).

It should be particularly mentioned that the N-type cobalt-doped layer 40 is made of cobalt-doped tin dioxide, which is synthesized by cobalt sulfate hydrate and tin chloride hydrate by appropriate concentration, the P-type semiconductor layer 30 is made of cuprous oxide (Cu₂O), and both the P-type semiconductor layer 30 and the N-type cobalt-doped layer 40 are respectively formed in a nanostructure which is selected from a group consisting of nanowire, nanoparticle, nanoblade, nanofiber and a combination thereof. Via optical characteristic analysis of oxide, it is known that the absorption spectrum of the cobalt-doped tin dioxide ranges from 700 nm to 1400 nm. The P-type semiconductor layer 30 is made of cuprous oxide (Cu₂O) having an absorption spectrum ranging from 300 nm to 800 nm. The combination of cobalt-doped tin dioxide and cuprous oxide (Cu₂O) can successfully absorb full spectrum of the sunlight. The P-type semiconductor layer 30 may be selectively made of copper oxide (CuO) or cobalt oxide (CO₃O₄).

The cobalt-doped tin dioxide does not need to be synthesized in a vacuum system. A solution process can be used to synthesize the nanostructure oxide of the P-type semiconductor layer 30 and the N-type cobalt-doped layer 40, whereby to fabricate a full-spectrum absorption solar cell. The fabrication process of the present invention comprises the following steps of:

Step S1: Fabricating the P-type semiconductor layer 30. The P-type semiconductor layer 30 is formed on the first electrode layer 20 that has been formed on the substrate 10. After the substrate 10 is performed by a hydrophilic process, the P-type semiconductor layer 30 is coated on the first electrode layer 20 by a spray method. Alternatively, the P-type semiconductor layer 30 may be coated on the first electrode layer 20 by a spray method, a spin coating method, a drop-casting method, an imprint method or an injection method.

Step S2: Fabricating the N-type cobalt-doped layer 40. Next, the N-type cobalt-doped layer 40 is coated on the P-type semiconductor layer 30 by a spray method. The N-type cobalt-doped layer 40 is made of cobalt-doped tin dioxide that is synthesized by cobalt sulfate hydrate and tin chloride hydrate by an appropriate concentration. In this embodiment, the N-type cobalt-doped layer 40 is coated on the P-type semiconductor layer 30 by a spray method. Alternatively, the N-type cobalt-doped layer 40 may be coated on the P-type semiconductor layer 30 by a spin coating method, a drop-casting method, an imprint method or an injection method.

Step S3: Fabricating the second electrode layer 50. The second electrode layer 50 is formed on the N-type cobalt-doped layer 40 by a hot pressing technique to complete the fabrication of the full-spectrum absorption solar cell of the present invention.

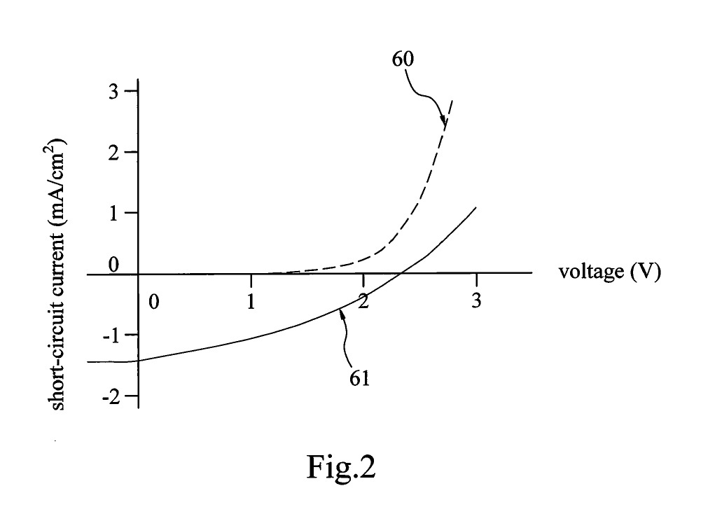

Refer to FIG. 2 a diagram schematically showing the voltage-current relationship of a full-spectrum absorption solar cell according to one embodiment of the present invention. As shown in FIG. 2, a non-illuminated curve 60 and an illuminated curve 61 are both obtained after the full-spectrum absorption solar cell of the present invention has been tested. The illuminated curve 61 indicates that the solar cell of the present invention has an open-circuit voltage of 2.33V and a short-circuit current of 1.43 mA/cm². The photocurrent of the illuminated solar cell is the difference of the short-circuit current respectively measured in the non-illuminated state and the illuminated state at the open-circuit voltage of zero. From the non-illuminated curve 60 and the illuminated curve 61, it is known that the solar cell of the present invention has a fill factor of 36.13% and power conversion efficiency of 1.2%.

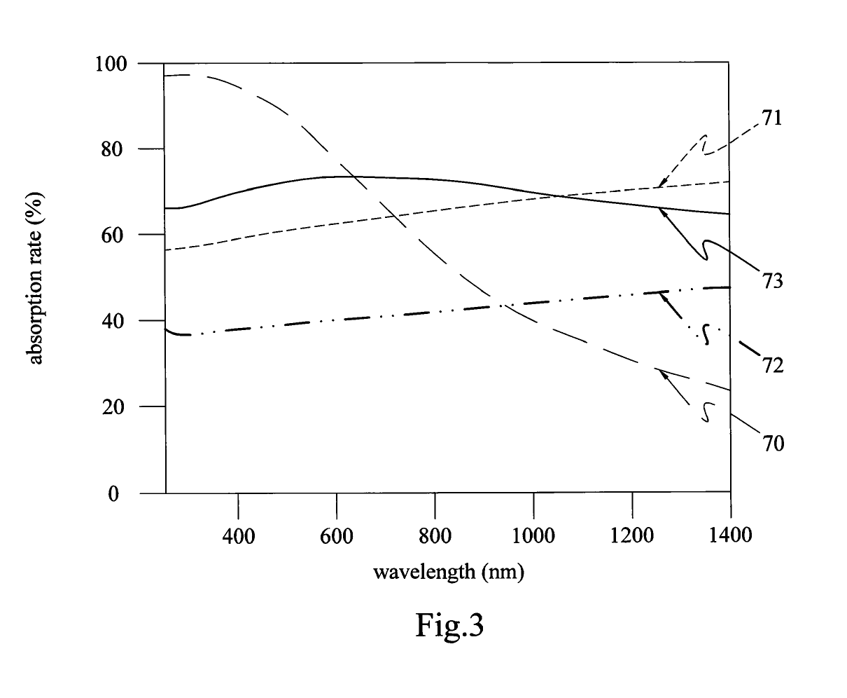

Refer to FIG. 3. Cuprous oxide used by the P-type semiconductor layer 30 has higher absorption capability in shorter wavelengths, as shown by the cuprous oxide absorption spectrum curve 70. There are three cobalt-doped tin dioxide absorption spectrum curves 71, 72 and 73 for tin dioxide respectively doped with 0.075 wt %, 0.025 wt % and 0.25 wt % of cobalt. For different cases, cobalt-doped tin dioxide having different weight percentages is respectively incorporated with the P-type semiconductor layer 30.

The N-type cobalt-doped layer 40 has ability to absorb full spectrum of the sunlight, and the P-type semiconductor layer 30 improves the absorption of shorter spectrum. Therefore, the solar cell of the present invention has better ability to absorb full spectrum of the sunlight. Further, the P-type semiconductor layer 30 and the N-type cobalt-doped layer 40 are respectively made of cuprous oxide and cobalt-doped tin dioxide, which are used to fabricate the solar cell of the present invention with a spray method in a hot pressing technique. Thereby, the solar cell of the present invention can be fabricated with a low cost in a mass production. The solar cell of the present invention is exempted from using the complicated multilayer structure and fabrication process but can still have the full spectrum absorption ability.

Furthermore, as the N-type semiconductor layer 40 is fabricated in a low-temperature environment, the substrate 10 can be made of a plastic material. Therefore, the present invention is exempted from using a high-temperature resistant substrate 10 made of glass or silicon chip. Moreover, the plastic substrate 10 is flexible and enables the present invention to have more applications than the rigid substrate 10. The most important of all, the conversion efficiency of the invention can achieve 1.2%, it is a significant improvement over the oxide-based nanostructures heterojunction solar cells in the world.

The present invention possesses utility, novelty and non-obviousness and meets the conditions for a patent. Thus, the Inventor files the application for a patent. It is appreciated if the patent is approved fast.

The embodiments described above are only to exemplify the present invention but not to limit the scope of the present invention. Any equivalent modification or variation according to the spirit of the present invention is to be also included within the scope of the present invention.

What is claimed is:

1. A full-spectrum absorption solar cell, comprising:
a substrate;
a first electrode layer formed on the substrate;
a P-type semiconductor layer arranged at one side of the first electrode layer far from the substrate and connected with the first electrode layer;
an N-type cobalt-doped layer arranged at one side of the P-type semiconductor layer far from the first electrode layer and connected with the P-type semiconductor layer, wherein the N-type cobalt-doped layer is made of cobalt-doped tin dioxide and connected with the P-type semiconductor layer to form a depletion layer at a junction thereof; and
a second electrode layer arranged at one side of the N-type cobalt-doped layer far from the first electrode layer and connected with the N-type cobalt-doped layer.

2. The full-spectrum absorption solar cell according to claim 1, wherein the substrate is made of a material selected from a group consisting of a silicon chip, glass and plastic.

3. The full-spectrum absorption solar cell according to claim 1, wherein the first electrode layer is made of a material selected from a group consisting of platinum, titanium and a combination thereof, and the second electrode layer is a transparent electrode.

4. The full-spectrum absorption solar cell according to claim 3, wherein the second electrode layer is made of a material selected from a group consisting of AZO (Aluminum-doped Zinc Oxide) and ITO (Indium Tin Oxide).

5. The full-spectrum absorption solar cell according to claim 4, wherein the second electrode layer is formed on the N-type cobalt-doped layer by a hot pressing fabrication process.

6. The full-spectrum absorption solar cell according to claim 1, wherein the P-type semiconductor layer is made of a material selected from a group consisting of cuprous oxide (Cu₂O), copper oxide (CuO) and cobalt oxide (CO₃O₄).

7. The full-spectrum absorption solar cell according to claim 6, wherein the P-type semiconductor layer is formed on the first electrode layer by a spray method, a spin coating method, a drop-casting method, an imprint method or an injection method after being performed by a hydrophilic process.

8. The full-spectrum absorption solar cell according to claim 1, wherein the N-type cobalt-doped layer is formed on the P-type semiconductor layer by a spray method, a spin coating method, a drop-casting method, an imprint method or an injection method.

9. The full-spectrum absorption solar cell according to claim 1, wherein the N-type cobalt-doped layer is synthesized by cobalt sulfate hydrate and tin chloride hydrate in a solution process.

10. The full-spectrum absorption solar cell according to claim 1, wherein the P-type semiconductor layer and the N-type cobalt-doped layer are respectively formed in a nanostructure selected from a group consisting of nanowire, nanoparticle, nanoblade, nanofiber and a combination thereof.
